(19) United States
(12) Patent Application Publication
(10) Pub. No.: US 2024/0153906 A1
(43) Pub. Date: May 9, 2024

(54) SUBSTRATE BONDING APPARATUS

(71) Applicant: SAMSUNG ELECTRONICS CO., LTD., Suwon-si (KR)

(72) Inventors: Byeongtak PARK, Suwon-si (KR); Gwanghee JO, Suwon-si (KR); Siwoong WOO, Suwon-si (KR); Jiwon SON, Suwon-si (KR); Yongjoo LEE, Suwon-si (KR); Hoechul KIM, Suwon-si (KR); Inhwa BAEK, Suwon-si (KR); Seungdae SEOK, Suwon-si (KR); Sehoon JANG, Suwon-si (KR); Jaehyun PHEE, Suwon-si (KR)

(21) Appl. No.: 18/386,687

(22) Filed: Nov. 3, 2023

(30) Foreign Application Priority Data
Nov. 3, 2022 (KR) 10-2022-0145558

(51) Int. Cl. H01L 23/00

(52) U.S. Cl. CPC H01L 24/74; H01L 2224/74; H01L 2924/40

(57) ABSTRACT

A substrate bonding apparatus includes a first bonding chuck having a first base, a deformable plate on the first base to support a first substrate, and a lower pressurer under the first base to apply pressure to the deformable plate, and a second bonding chuck vertically spaced apart from the first bonding chuck and having a second base to fix a second substrate, and an upper pressurer to apply pressure to the second substrate. The deformable plate includes an outer portion surrounding a center portion, a bottom surface of the outer portion of the deformable plate being adhered to the first base, the center portion being deformable in the vertical direction by the lower pressurer, and thicknesses of the center and outer portions of the deformable plate in the vertical direction being different from each other.

### CROSS-REFERENCE TO RELATED APPLICATION

This application is based on and claims priority under 35 U.S.C. § 119 to Korean Patent Application No. 10-2022-0145558, filed on Nov. 3, 2022, in the Korean Intellectual Property Office, the disclosure of which is incorporated by reference herein in its entirety.

### BACKGROUND

### 1. Field

Embodiments relate to a semiconductor substrate bonding apparatus, and more particularly, to a substrate bonding apparatus capable of improving the reliability of a bonding process.

### 2. Description of the Related Art

In a process of manufacturing a semiconductor device, a substrate bonding process for bonding two or more substrates may be performed. Such a substrate bonding process may be performed to improve a mounting density of semiconductor chips in a semiconductor device. For example, a semiconductor module having a structure in which semiconductor chips are stacked may be advantageous in improving a mounting density of the semiconductor chips, shortening a length of wires between the semiconductor chips, and processing a high-speed signal.

When manufacturing a semiconductor module having a stacked semiconductor chip structure, a process of bonding wafers and cutting the wafers into stacked semiconductor chips may have greater productivity than a process of bonding semiconductor chips. A substrate bonding process may be performed by using a wafer-to-wafer method in which two wafers are directly bonded without a separate medium.

The wafer-to-wafer method may typically be performed by using a bonding apparatus including bonding chucks for supporting wafers and components for pressing the wafers.

### SUMMARY

According to an aspect of embodiments, there is provided a substrate bonding apparatus. The substrate bonding apparatus includes a first bonding chuck including a first base, a deformable plate supporting a first substrate on the first base, and a lower pressurer applying pressure to a bottom surface of the deformable plate, and a second bonding chuck including a second base fixing an outer portion of a second substrate disposed opposite to the first substrate in a vertical direction and an upper pressurer applying pressure to a top surface of the second substrate, wherein an outer portion of the bottom surface of the deformable plate is adhered to the first base and is deformable in the vertical direction by being pressed by the lower pressurer, and a thickness of a center portion of the deformable plate in the vertical direction and a thickness of an outer portion of the deformable plate in the vertical direction are different from each other.

According to another aspect of embodiments, there is provided a substrate bonding apparatus including a first bonding chuck including a first base, a deformable plate supporting a first substrate on the first base, and a lower pressurer applying pressure to a bottom surface of the deformable plate, a driving unit coupled to a lower portion of the first bonding chuck and configured to adjust a position of the first bonding chuck, a second bonding chuck including a second base fixing an outer portion of a second substrate disposed opposite to the first substrate in a vertical direction and an upper pressurer applying pressure to a top surface of the second substrate, and an imaging unit configured to obtain alignment images regarding the first substrate and the second substrate above an upper portion of the second bonding chuck, wherein an outer portion of the bottom surface of the deformable plate is adhered to the first base and is deformable in the vertical direction by being pressed by the lower pressurer, and a thickness of a center portion of the deformable plate in the vertical direction and a thickness of an outer portion of the deformable plate in the vertical direction are different from each other.

According to another aspect of embodiments, there is provided a substrate bonding apparatus including a first bonding chuck including a first base, a deformable plate supporting a first substrate on the first base, and a lower pressurer applying pressure to a bottom surface of the deformable plate, a driving unit coupled to a lower portion of the first bonding chuck and configured to adjust a position of the first bonding chuck, a second bonding chuck including a second base fixing an outer portion of a second substrate disposed opposite to the first substrate in a vertical direction and an upper pressurer applying pressure to a top surface of the second substrate, and an imaging unit configured to obtain alignment images regarding the first substrate and the second substrate above an upper portion of the second bonding chuck, wherein an outer portion of the bottom surface of the deformable plate is adhered to the first base and is deformable in the vertical direction by being pressed by the lower pressurer, and the thickness of a portion of the deformable plate in the vertical direction nearby a center portion of the deformable plate is greater than the thickness of a portion of the deformable plate in the vertical direction nearby an outer portion of the deformable plate, the lower pressurer includes a lower center pressing member for applying pressure to the center portion of a bottom surface of the first substrate and a lower outer pressing member for applying pressure to an outer portion of the bottom surface of the first substrate, a plurality of lower outer pressing members are provided and arranged, such that respective horizontal distances from the plurality of lower outer pressing members to the lower center pressing member are substantially the same and center angles between adjacent lower outer pressing members are substantially the same.

### BRIEF DESCRIPTION OF THE DRAWINGS

Features will become apparent to those of skill in the art by describing in detail exemplary embodiments with reference to the attached drawings, in which:

FIG. 1 is a schematic perspective view of a substrate bonding apparatus according to embodiments;

FIG. 2 is a cross-sectional view of a substrate bonding apparatus according to embodiments;

FIG. 3 is a flowchart of a substrate bonding method according to embodiments;

FIGS. 4A to 4E are cross-sectional views of stages in a substrate bonding method according to embodiments;

FIG. 5 is a schematic diagram showing a first region and a second region of a first substrate disposed in a substrate bonding apparatus according to embodiments;

FIGS. 6A and 6B are schematic diagrams showing the position of a lower pressurer of a substrate bonding apparatus according to embodiments;

FIGS. 7A to 7E are schematic diagrams showing a deformable plate of a substrate bonding apparatus according to embodiments; and

FIGS. 8A and 8B are schematic diagrams showing shapes of a first base of a substrate bonding apparatus according to embodiments.

### DETAILED DESCRIPTION

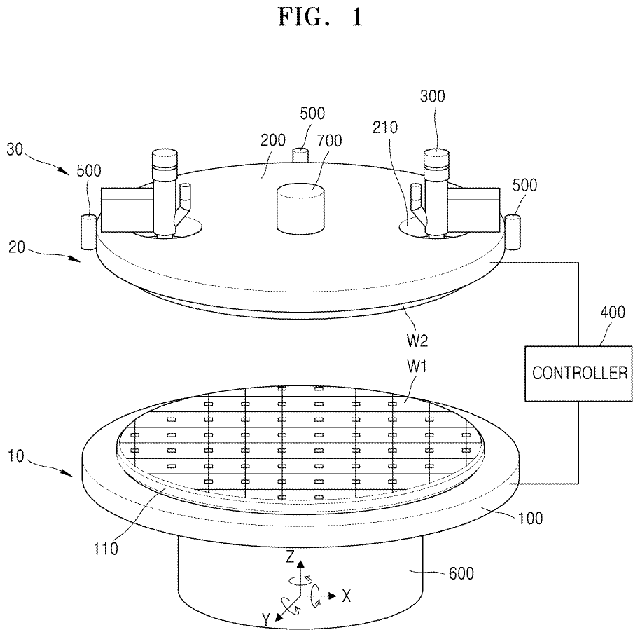

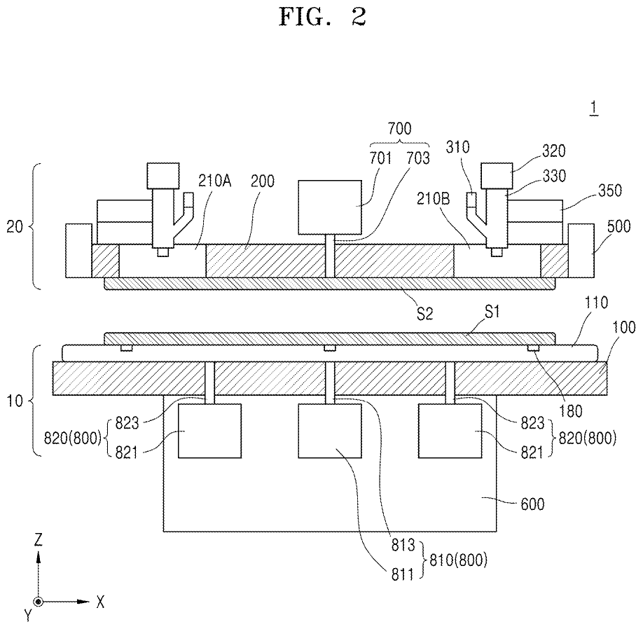

FIG. 1 is a schematic perspective view of a substrate bonding apparatus according to embodiments. FIG. 2 is a cross-sectional view of a substrate bonding apparatus according to embodiments.

Referring to FIGS. 1 and 2, a substrate bonding apparatus 1 according to embodiments may include a first bonding chuck 10, a second bonding chuck 20, a lower pressing unit 800, an upper pressing unit 700, and a substrate alignment device 30.

The first bonding chuck 10 may support the bottom surface of a first substrate S1. According to example embodiments, the bottom surface of the first substrate S1 may be an inactive surface of the first substrate S1. In the drawings, the X-axis direction and the Y-axis direction indicate directions parallel to the top surface or the bottom surface of the first substrate S1, and the X-axis direction and the Y-axis direction may be directions perpendicular to each other. The Z-axis direction may indicate a direction perpendicular to the top surface or the bottom surface of the first substrate S1. In other words, the Z-axis direction may be a direction perpendicular to the X-Y plane. Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

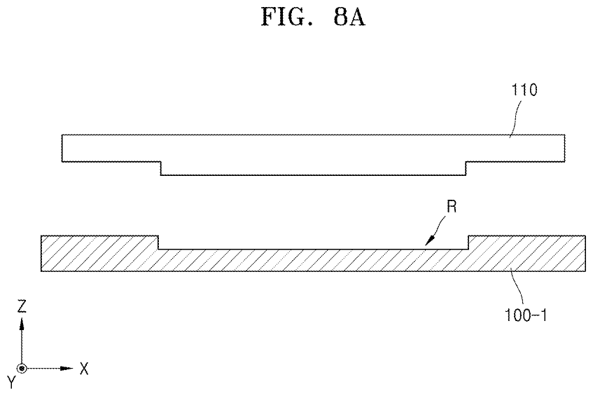

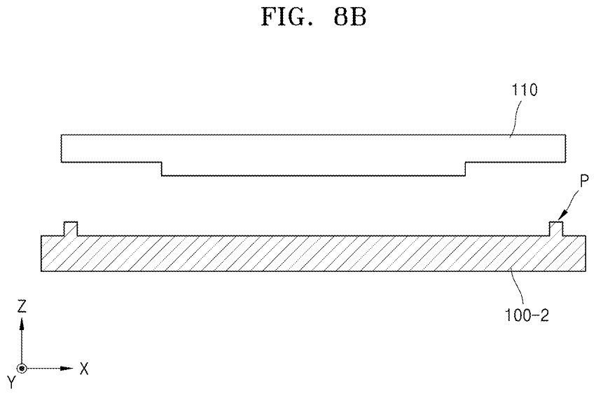

The first bonding chuck 10 may include a first base 100 and a deformable plate 110 attached onto the first base 100. The first base 100 may be disposed below the deformable plate 110 to fix the outer portion of the bottom surface of the deformable plate 110. According to embodiments, the first base 100 may fix the outer portion of the bottom surface of the deformable plate 110 on the first base 100 through vacuum pressure. However, embodiments are not limited thereto, e.g., the outer portion of the bottom surface of the deformable plate 110 may be bonded to the top surface of the first base 100, and thus the deformable plate 110 may be integrated with the first base 100. The shape of the first base 100 fixed to the deformable plate 110 will be described later in detail with reference to FIGS. 8A and 8B.

The first base 100 may have holes into which a center pressing pin 813 and outer pressing pins 823 of the lower pressing unit 800 (i.e., lower pressure) are inserted. The holes may be provided in the same shape as those of the center pressing pin 813 and the outer pressing pins 823.

The deformable plate 110 may be positioned, e.g., directly, on the first base 100 to support the bottom surface of the first substrate S1, e.g., so the deformable plate 110 may be between the first base 100 and the first substrate S1. According to example embodiments, the deformable plate 110 may include vacuum grooves 180 in which vacuum pressure may be formed, e.g., the vacuum grooves 180 may extend from the upper surface of the deformable plate 110 toward the first base 100. The first bonding chuck 10 may fix the first substrate S1 by using the vacuum grooves 180 in which vacuum pressure is formed. For example, the first bonding chuck 10 may further include a vacuum pump for applying vacuum pressure to the vacuum grooves 180, wherein, when vacuum pressure is formed in the vacuum grooves 180 by the vacuum pump, the first substrate S1 may be vacuum adsorbed onto the deformable plate 110. Also, when the vacuum pressure is released from the vacuum grooves 180 by the vacuum pump, the first substrate S1 may be separated from the deformable plate 110 as the vacuum adsorption by the deformable plate 110 is released.

According to other embodiments, the deformable plate 110 may be configured to support the first substrate S1 by using an electrostatic force. When the deformable plate 110 is configured to fix the first substrate S1 by using an electrostatic force, the deformable plate 110 may include an electrode that receives power to generate electrostatic force for fixing the first substrate S1.

The deformable plate 110 may be mounted on the first base 100, such that the distance to the first base 100 is variable. In other words, the deformable plate 110 may be physically pressed and deformed. For example, the outer portion of the deformable plate 110 may be fixed to the first base 100, whereas the inner portion of the deformable plate 110 inside, e.g., surrounded by, the fixed outer portion may not be fixed to the first base 100. In other words, the outer portion of the bottom surface of the deformable plate 110 (e.g., a ring-shaped peripheral portion of the bottom surface of the deformable plate 110 facing the first base 100) may be fixed to the first base 100, and the center portion of the bottom surface of the deformable plate 110 (e.g., a portion of the bottom surface of the deformable plate 110 surrounded by the outer portion) may not be fixed to the first base 100.

Therefore, when an external force (e.g., an external force in the vertical direction Z) is applied to the bottom surface of the deformable plate 110, the deformable plate 110 may be convexly deformed by the external force. For example, when pressure is applied to the bottom surface of the deformable plate 110 by the lower pressing unit 800, a portion of the deformable plate 110 inside the fixed outer portion of the deformable plate 110 may be convexly deformed upward, e.g., bulge away from the first base 100, while the deformable plate 110 is supporting the first substrate S1.

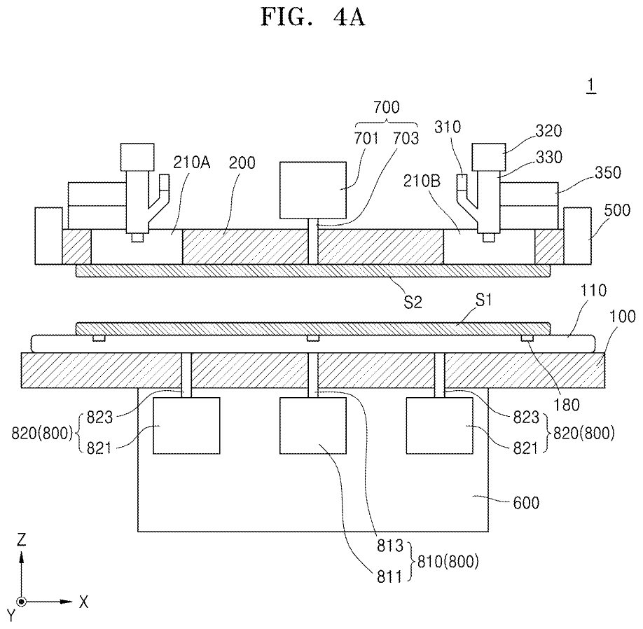

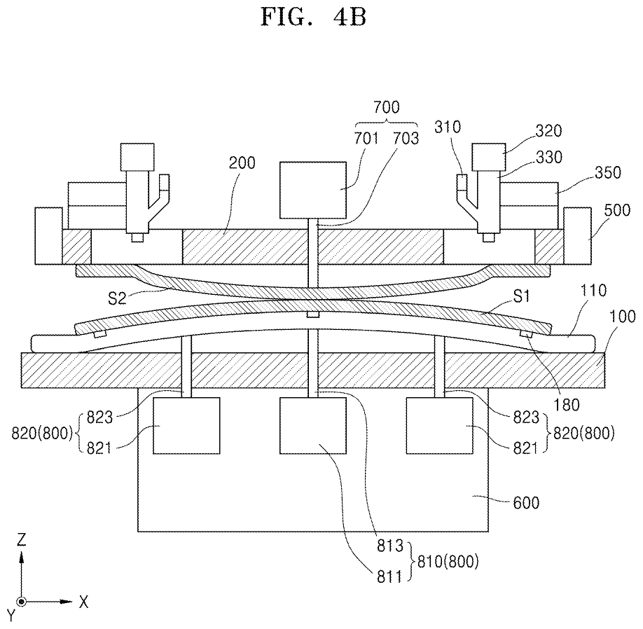

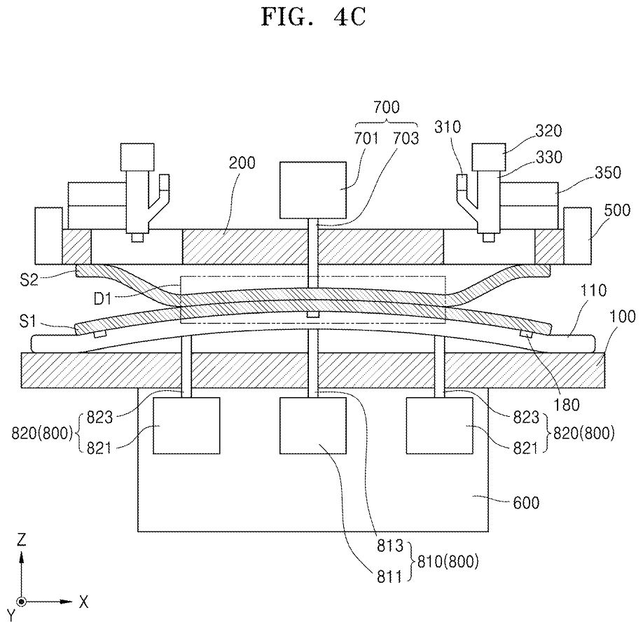

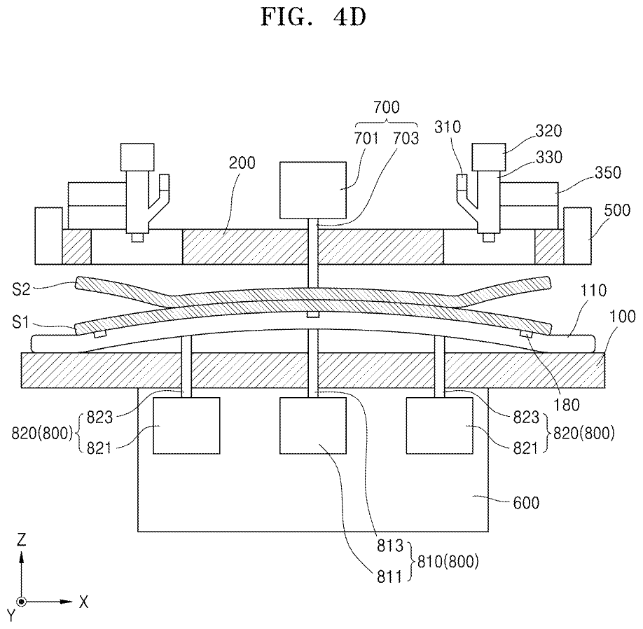

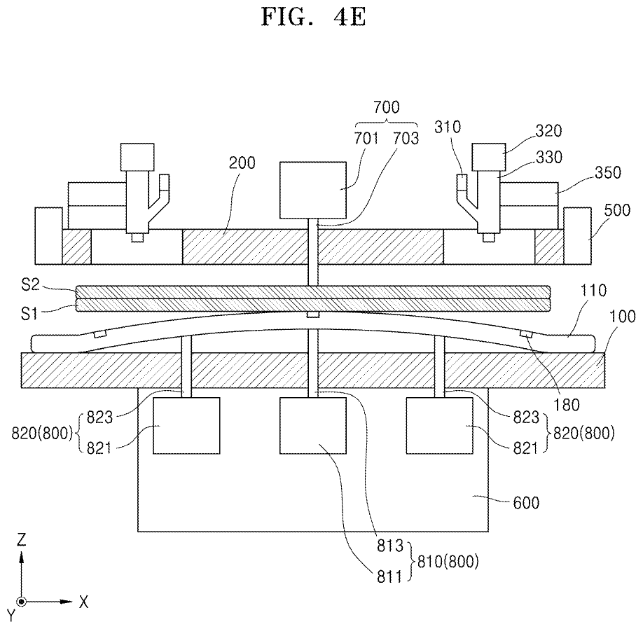

Since the deformable plate 110 is deformed while supporting the first substrate S1, and the first substrate S1 is fixed to the deformable plate 110, the first substrate S1 may be forcibly deformed due to the deformation of the deformable plate 110. For example, the deformable plate 110 may be convexly deformed upward by the lower pressing unit 800 while the first substrate S1 is vacuum-adsorbed to the deformable plate 110, so the first substrate S1 may be forcibly deformed to be convexed upward in correspondence to the deformation of the deformable plate 110 (FIG. 4B). In this case, the curvature of the forcibly deformed first substrate S1 may be controlled by the curvature of the deformable plate 110. In other words, the first substrate S1 may be deformed into the same shape as the deformed shape of the deformable plate 110.

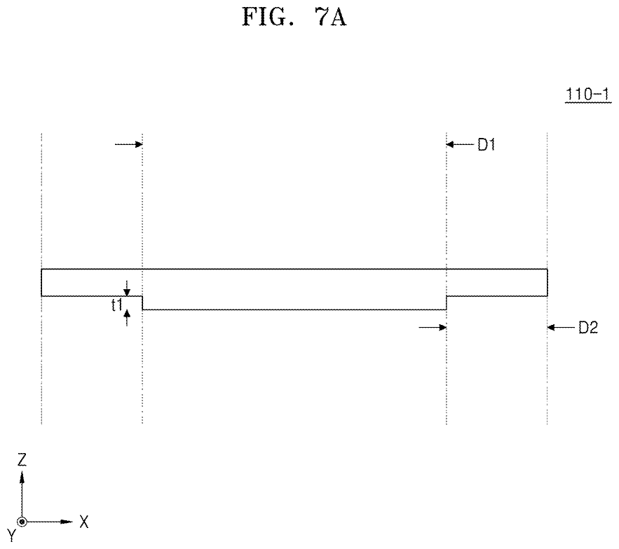

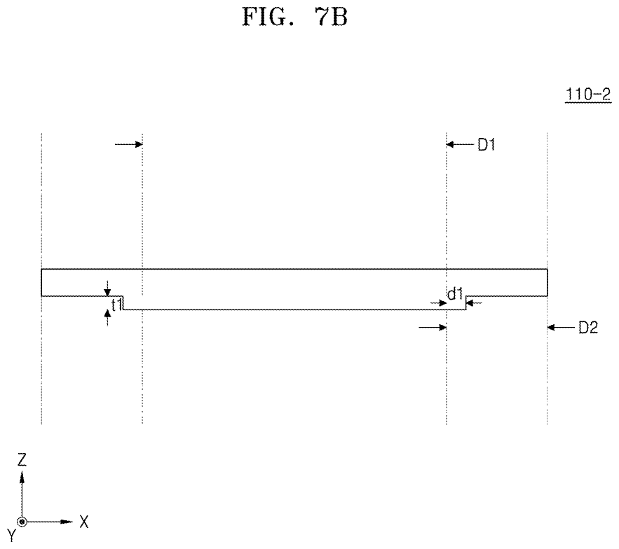

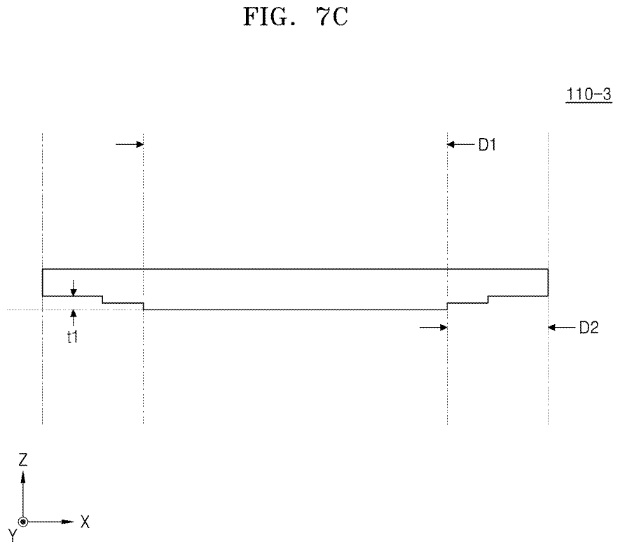

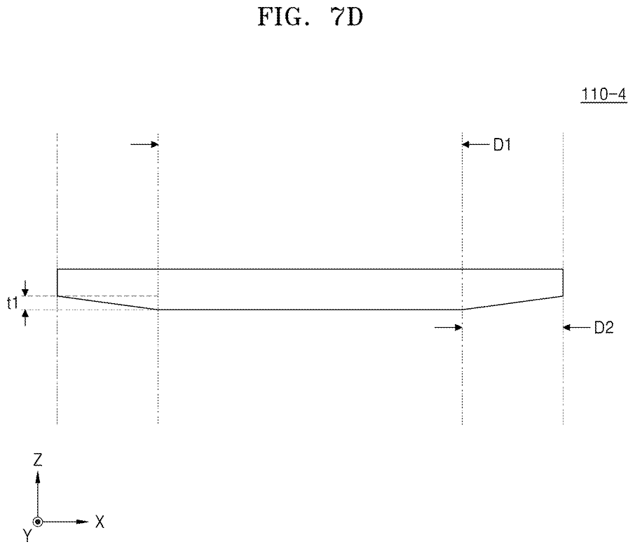

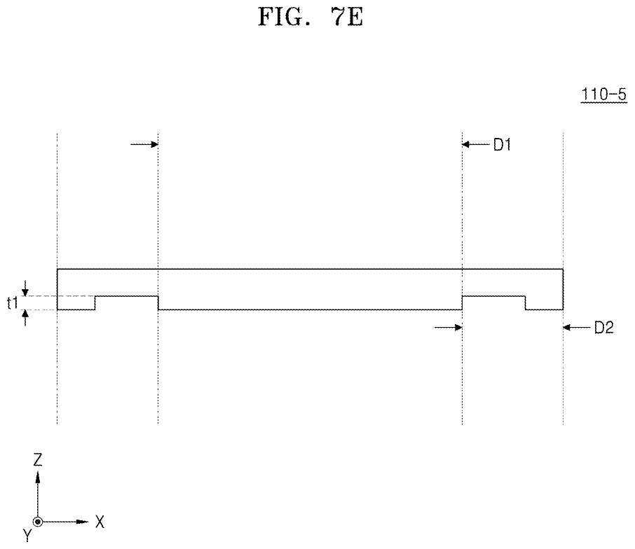

The thickness of the deformable plate 110 in the vertical direction Z may not be constant. According to example embodiments, the thickness of the center portion of the deformable plate 110 in the vertical direction Z and the thickness of the outer portion of the deformable plate 110 in the vertical direction Z may be different from each other. The shape of the deformable plate 110 due to different thicknesses of the deformable plate 110 in the vertical direction Z will be described later in detail with reference to FIGS. 7A to 7E.

According to embodiments, the deformable plate 110 may include a metal, ceramic, rubber, or a combination thereof. For example, the deformable plate 110 may include aluminum or silicon carbide (SiC).

The second bonding chuck 20 may be configured to support a second substrate S2 disposed to face the first substrate S1 in the vertical direction Z. According to embodiments, the second bonding chuck 20 may be disposed to face the first bonding chuck 10 in the vertical direction Z and fix the second substrate S2, such that the bottom surface of the second substrate S2 faces the top surface of the first substrate S1. Here, the bottom surface of the second substrate S2 may be the active surface of the second substrate S2, and the top surface of the first substrate S1 may be the active surface of the first substrate S1.

The second bonding chuck 20 may be positioned on the top surface of the second substrate S2. In other words, the second bonding chuck 20 may be disposed to be spaced apart from the first bonding chuck 10 in the vertical direction Z with the first substrate S1 and the second substrate S2 therebetween.

The second bonding chuck 20 may include a second base 200. The second base 200 may be configured to fix the second substrate S2. According to embodiments, the second base 200 may fix the top surface of the second substrate S2 onto the bottom surface of the second base 200 by using vacuum pressure. According to other embodiments, the second base 200 may be configured to support the second substrate S2 by using an electrostatic force.

Observation windows 210 penetrating from the top surface of the second base 200 to the bottom surface of the second base 200 may be formed in at least two portions of the second base 200. The observation windows 210 may be regions for an imaging unit 300 (i.e., an imager) to capture images of the first substrate S1 and the second substrate S2. The observation windows 210 may be formed as holes penetrating through the second base 200, and thus the top surface of the second substrate S2 may be exposed at the bottom surface of the observation windows 210. However, the observation windows 210 are not limited thereto and may have a structure in which light-transmitting material covers may be arranged in the holes according to embodiments.

The second base 200 may have a hole into which an upper pressing pin 703 of the upper pressing unit 700 (i.e., an upper pressurer) is inserted. According to embodiments, holes into which upper pressing pins 703 of the upper pressing unit 700 are inserted may be formed at the center of the second base 200.

The lower pressing unit 800 may be configured to apply pressure to the bottom surface of the first substrate S1. According to example embodiments, the lower pressing unit 800 may include a lower center pressing member 810 and lower outer pressing members 820, e.g., the lower outer pressing members 820 may be in the periphery of the lower center pressing member 810.

The lower center pressing member 810 may be disposed under the first base 100 to apply pressure to the center of the bottom surface of the deformable plate 110, e.g., the lower center pressing member 810 may be disposed at the center of the bottom of the first base 100. According to some embodiments, the lower center pressing member 810 may include the center pressing pin 813 and a center actuator 811 coupled to the center pressing pin 813. The center pressing pin 813 may have a cylindrical shape extending in the vertical direction Z. The center pressing pin 813 may pass through a hole formed in the center of the first base 100 and contact the center of the bottom surface of the deformable plate 110. The center actuator 811 may drive the center pressing pin 813 up and down. That is, the center actuator 811 may reciprocate, e.g., move, the center pressing pin 813 in the vertical direction Z. According to some embodiments, the center actuator 811 may include, e.g., a stacked piezoelectric actuator, a voice coil motor, a rack and pinion combined with a motor, etc.

The lower outer pressing members 820 may be coupled to the bottom surface of the first base 100 to apply pressure to the outer portion of the bottom surface of the deformable plate 110. At this time, the outer portion of the deformable plate 110 subjected to pressure may be located inside the outer portion of the deformable plate 110 bonded to the first base 100.

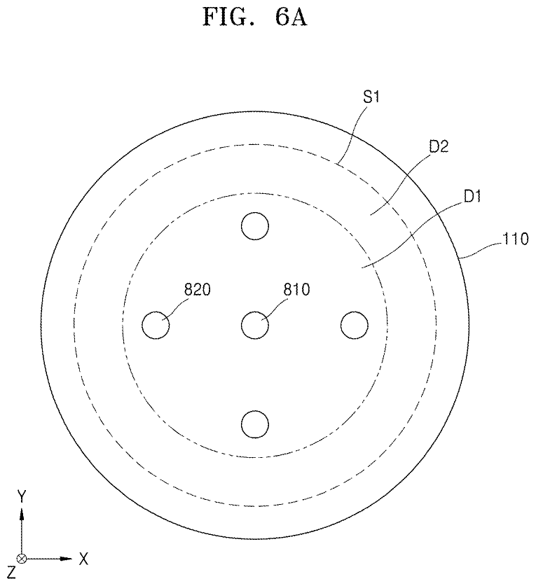

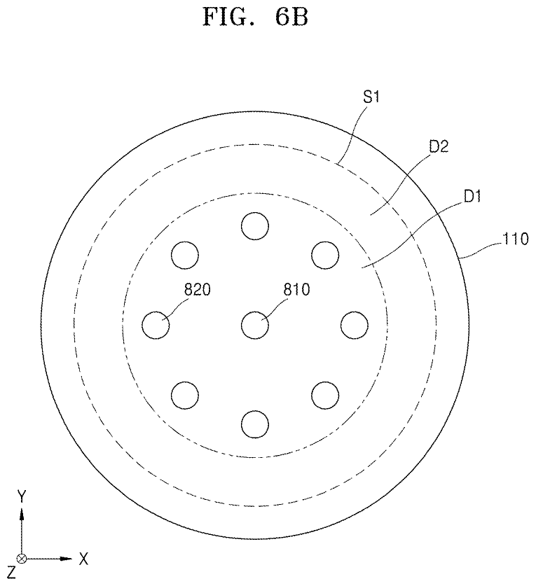

A plurality of lower outer pressing members 820 may be provided. Positions where the plurality of lower outer pressing members 820 are arranged will be described later in detail with reference to FIGS. 6A and 6B.

According to some embodiments, the lower outer pressing members 820 may each include an outer pressing pin 823 and an outer actuator 821. The outer pressing pin 823 may have a cylindrical shape extending in the vertical direction Z. The outer pressing pins 823 may pass through holes formed in the outer portion of the first base 100 and contact the outer portion of the bottom surface of the deformable plate 110.

The outer actuator 821 may drive the outer pressing pin 823 up and down. In other words, the outer actuator 821 may reciprocate, e.g., move, the outer pressing pin 823 in the vertical direction Z. According to some embodiments, the outer actuator 821 may include, e.g., a stacked piezoelectric actuator, a voice coil motor, a rack and pinion combined with a motor, etc.

According to example embodiments, the length of the outer pressing pin 823 in the vertical direction Z may be shorter than the length of the center pressing pin 813 in the vertical direction Z, e.g., an extension length of the outer pressing pin 823 in the vertical direction Z may be shorter than an extension length of the center pressing pin 813 in the vertical direction Z (FIG. 4B). In other words, as a horizontal distance (i.e., in a horizontal direction X or Y) between a pressing pin that applies pressure to the center of the deformable plate 110 to a pressing pin that applies pressure to a non-central portion of the bottom surface of the deformable plate 110 increases, the length (e.g., a maximal extension) of the pressing pin in the vertical direction Z may decrease. For example, the protruding length of the outer pressing pin 823 from the first base 100 may be smaller than the protruding length of the center pressing pin 813 from the first base 100. Also, the top surface of the outer pressing pin 823 may be positioned at a level lower than that of the top surface of the center pressing pin 813 in the vertical direction Z, e.g., relative to a bottom of the first base 100. However, embodiments are not limited thereto, e.g., the lengths of the outer pressing pin 823 and the center pressing pin 813 in the vertical direction Z may be identical to each other or the length of the center pressing pin 813 in the vertical direction Z may be smaller than the length of the outer pressing pin 823 in the vertical direction Z. For example, the outer pressing pins 823 may be moved independently, e.g., and extend to different lengths, of each other and of the center pressing pin 813 to push and adjust a curvatures of the deformable plate 110.

The upper pressing unit 700 may be configured to apply pressure to the top surface of the second substrate S2. According to embodiments, the upper pressing unit 700 may be disposed on the second bonding chuck 20 to apply pressure to the center of the top surface of the second substrate S2.

According to some embodiments, the upper pressing unit 700 may include the upper pressing pin 703 and an upper actuator 701 coupled to the upper pressing pin 703. The upper pressing pin 703 may pass through a hole formed in the center of the second base 200 and contact the center of the top surface of the second substrate S2. In other words, the upper actuator 701 may reciprocate the upper pressing pin 703 in the vertical direction Z.

The substrate alignment device 30 may include the imaging unit 300 that obtains images of the first substrate S1 disposed on the first bonding chuck 10 and the second substrate S2 disposed on the second bonding chuck 20, a driving unit 600 (i.e., a driver) for aligning the position of the first bonding chuck 10, and a distance sensor 500 for measuring a distance between the first bonding chuck 10 and the second bonding chuck 20 in the vertical direction Z.

The imaging unit 300 may be coupled to and disposed on the second bonding chuck 20. The imaging unit 300 may be configured to obtain aligned images of the first substrate S1 and the second substrate S2.

The imaging unit 300 may include a light source 310, a body unit 330, a camera 320, and a first moving stage 350. The light source 310 may be configured to emit transmission light. The body unit 330 provides a path through which light travels, and may include, e.g., a lens barrel. The transmission light emitted from the light source 310 travels along the body unit 330 and is emitted from the lower end of the body unit 330, and the emitted light may be irradiated toward the second substrate S2 disposed on the first bonding chuck 10. At this time, a part of the transmitted light irradiated toward the second substrate S2 may be transmitted through the second substrate S2 and irradiated to the first substrate S1.

As a result, the transmission light emitted from the imaging unit 300 may be transmitted through the second substrate S2 and irradiated to the first substrate S1. Also, measurement light reflected from the first substrate S1 may be transmitted through the second substrate S2 and focused on the imaging unit 300. Therefore, even when the second substrate S2 is disposed between the imaging unit 300 and the first substrate S1, the imaging unit 300 may capture an image of the first substrate S1. The imaging unit 300 may capture images of the first substrate S1 and the second substrate S2 a plurality of times and transmit the obtained images to a controller 400.

According to embodiments, the body unit 330 may be configured, such that a path in which transmission light emitted from the light source 310 travels and a path in which measurement light reflected by the first substrate S1 and the second substrate S2 and incident on the camera 320 are different from each other. According to example embodiments, an objective lens may be disposed at the lower end of the body unit 330. A second moving stage for finely moving the objective lens may be disposed between the body unit 330 and the objective lens.

The camera 320 may be configured to capture images of the first substrate S1 and the second substrate S2. The camera 320 may receive measurement light reflected from surfaces of the first substrate S1 and the second substrate S2. For example, the camera 320 may include an infrared camera.

The first moving stage 350 may be fixed to the top surface of the second bonding chuck 20 and move the body unit 330 in the first horizontal direction X and/or the second horizontal direction Y.

The driving unit 600 may be disposed under the first bonding chuck 10. The driving unit 600 may be responsible for horizontal movement, vertical movement, rotational movement, and/or tilting movement of the first bonding chuck 10. The driving unit 600 may include a six-axis stage, and thus, the driving unit 600 may move the first bonding chuck 10 in the first horizontal direction X, the second horizontal direction Y, and the vertical direction Z or rotate the first bonding chuck 10 around the X axis, the Y axis, and the Z axis. Therefore, the driving unit 600 may align the first substrate S1 and the second substrate S2 by moving the first bonding chuck 10 on which the first substrate S1 is disposed.

The distance sensor 500 is disposed around the second bonding chuck 20 and may detect a distance between the top surface of the first bonding chuck 10 and the bottom surface of the second bonding chuck 20 in the vertical direction Z. According to some embodiments, the distance sensor 500 may irradiate an electromagnetic wave to the first bonding chuck 10 and then analyzes an electromagnetic wave reflected from the first bonding chuck 10, thereby measuring a distance between the first bonding chuck 10 and the second bonding chuck 20 in the vertical direction Z. According to some embodiments, a plurality of distance sensors 500 may be arranged along the circumference of the second bonding chuck 20. Parallelism between the first bonding chuck 10 and the second bonding chuck 20 may be measured by the plurality of distance sensors 500. Also, the distance between the first substrate S1 and the second substrate S2 in the vertical direction Z may be measured by subtracting thicknesses of the first substrate S1 and the second substrate S2 measured in advance from the distance between the first bonding chuck 10 and the second bonding chuck 20 in the vertical direction Z.

The controller 400 may control the first bonding chuck 10, the second bonding chuck 20, and the substrate alignment device 30 to align the first substrate S1 and the second substrate S2. According to embodiments, the controller 400 may determine alignment errors of the first substrate S1 and the second substrate S2 based on alignment images of the first substrate S1 and the second substrate S2 obtained by the substrate alignment device 30 and correct the alignment errors by driving the driving unit 600. The controller 400 may control the first bonding chuck 10 to fix or separate the first substrate S1 and control the second bonding chuck 20 to fix or separate the second substrate S2. Also, the controller 400 may control the driving of the lower outer pressing members 820 of the lower pressing unit 800 according to the deformation state of the first substrate S1 due to the driving of the lower pressing unit 800. For example, when a first side of the first substrate S1 has a smaller curvature than a second side, the lower outer pressing members 820 arranged near the first side of the first substrate S1 may be further driven in the vertical direction Z to increase the curvature of the first side.

The controller 400 may be implemented in hardware, firmware, software, or any combination thereof. For example, the controller 400 may include a computing device, e.g., a workstation computer, a desktop computer, a laptop computer, and a tablet computer. The controller 400 may include a simple controller, a complex processor (e.g., a microprocessor, a center processing unit (CPU), and a graphics processing unit (GPU), a processor configured by software, dedicated hardware, or firmware. The controller 400 may be implemented by, e.g., a general-purpose computer or application-specific hardware like a digital signal processor (DSP), a field programmable gate array (FPGA), and an application specific integrated circuit (ASIC). The controller 400 may be implemented as instructions stored on a machine-readable medium that may be read and executed by one or more processors. Here, a machine-readable medium may include any mechanism for storing and/or transmitting information in a form readable by a machine (e.g., a computing device). For example, machine-readable media may include read-only memories (ROM), random access memories (RAM), magnetic disk storage media, optical storage media, and flash memory devices, and may have recorded thereon electrical, optical, acoustic, or other forms of radio frequency signals (e.g., carrier waves, infrared signals, digital signals, etc.) and any other signal.

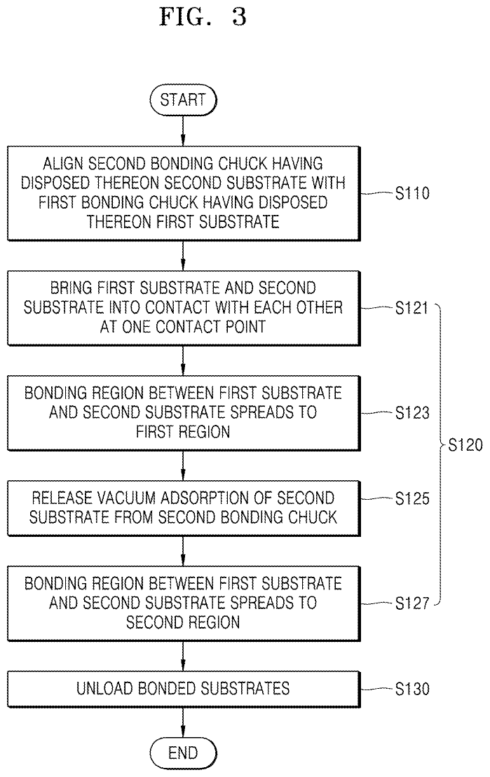

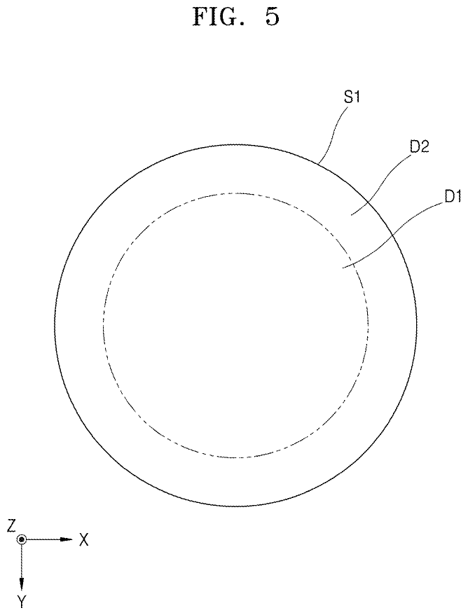

FIG. 3 is a flowchart of a substrate bonding method according to embodiments. FIGS. 4A to 4E are cross-sectional views of stages in a substrate bonding method according to embodiments. FIG. 5 is a schematic diagram showing a first region and a second region of a first substrate disposed in a substrate bonding apparatus according to embodiments. Hereinafter, a substrate bonding method using a substrate bonding apparatus according to embodiments will be described in detail with reference to FIGS. 3, 4A to 4E, and 5. Also, descriptions identical to those given above with reference to FIGS. 1 and 2 will be omitted.

Referring to FIGS. 3 and 4A, the second bonding chuck 20 (on which the second substrate S2 is disposed) is aligned with the first bonding chuck 10 (on which the first substrate S1 is disposed) (operation S1100).

In operation S110, the first substrate S1 may be mounted on the first bonding chuck 10, such that the inactive surface of the first substrate S1 is in contact with the first bonding chuck 10 (i.e., with the top surface of the deformable plate 110), and the second substrate S2 may be mounted on the second bonding chuck 20, such that the inactive surface of the second substrate S2 is in contact with the second bonding chuck 20 (i.e., with the bottom surface of the second base 200). For example, the first bonding chuck 10 may vacuum-adsorb the first substrate S1, such that the first substrate S1 is fixed on the top surface of the deformable plate 110, and the second bonding chuck 20 may vacuum-adsorb the second substrate S2, such that the second substrate S2 is fixed to the bottom surface of the second base 200. The bottom surface of the second substrate S2 mounted on the second bonding chuck 20 may face the top surface of the first substrate S1 mounted on the first bonding chuck 10.

In operation S110l the first bonding chuck 10 and the second bonding chuck 20 may be aligned in the horizontal direction X or Y and the vertical direction Z. For alignment of the first bonding chuck 10 and the second bonding chuck 20, at least one of the first bonding chuck 10 and the second bonding chuck 20 may be moved or rotated in the horizontal direction X or Y and may also be moved or rotated in the vertical direction Z.

In operation S110, the second bonding chuck 20 may descend toward the first bonding chuck 10, thereby separating the top surface of the first substrate S1 and the bottom surface of the second substrate S2 apart from each other by a pre-set appropriate distance. For example, the second bonding chuck 20 may descend toward the first bonding chuck 10 only a predetermined distance during alignment, e.g., so the top surface of the first substrate S1 and the bottom surface of the second substrate S2 may be vertically spaced apart from each other during alignment. For example, to adjust the distance between the first substrate S1 and the second substrate S2, the first bonding chuck 10 may be raised, or the first bonding chuck 10 may be raised and the second bonding chuck 20 may be lowered simultaneously.

Referring to FIG. 3, after the first bonding chuck 10 and the second bonding chuck 20 are aligned, bonding between the first substrate S1 and the second substrate S2 is performed (operation S120). According to embodiments, the bonding between the first substrate S1 and the second substrate S2 may include bringing the first substrate S1 and the second substrate S2 into contact with each other at one contact point (operation S121), spreading a bonding region between the first substrate S1 and the second substrate S2 to a first region D1 (operation S123), releasing vacuum adsorption of the second substrate S2 from the second bonding chuck 20 (operation S125), and spreading the bonding region between the first substrate S1 and the second substrate S2 to a second region (D2) (operation S127).

Referring to FIGS. 3 and 4B, to initiate bonding between the first substrate S1 and the second substrate S2 in operation S121, pressure is applied to the bottom surface of the deformable plate 110 by using the lower pressing unit 800, and pressure is applied to the top surface of the second substrate S2 by using the upper pressing unit 700. At this time, the upper pressing unit 700 may apply pressure to the center of the top surface of the second substrate S2. As described above with reference to FIGS. 1 and 2, pressing of the upper pressing unit 700 and the lower pressing unit 800 may be performed by a pressing pin and an actuator.

As the lower pressing unit 800 presses the bottom surface of the deformable plate 110, the deformable plate 110 may be deformed convexly upward, and the first substrate S1 may also be deformed convexly upward. At this time, since the lower pressing unit 800 further includes the lower outer pressing members 820 in addition to the lower center pressing member 810, the deformable plate 110 may be accurately deformed into a desired shape. For example, when a first side of the first substrate S1 has a smaller curvature than a second side, the lower outer pressing members 820 arranged near the first side of the first substrate S1 may be further driven in the vertical direction Z to increase the curvature of the first side. As a result, the curvature of the deformable plate 110 may be constantly deformed through the lower center pressing member 810 and the lower outer pressing members 820.

In the same regard, the upper pressing unit 700 applies pressure to the center of the top surface of the second substrate S2. As the upper pressing unit 700 presses the center of the second substrate S2, the center region of the second substrate S2 pressed by the upper pressing unit 700 is deformed convexly downward, and the first substrate S1 and the second substrate S2 may contact each other at one contact point. The one contact point may be defined as a bonding initiation point where bonding of the first substrate S1 and the second substrate S2 is initiated. For example, the bonding initiation point may be a point where the center of the top surface of the first substrate S1 and the center of the bottom surface of the second substrate S2 meet each other.

Referring to FIGS. 3 and 4C, in operation S123, the bonding region between the first substrate S1 and the second substrate S2 may gradually spread from the bonding initiation point toward the outer regions of the first substrate S1 and the second substrate S2. The bonding region between the first substrate S1 and the second substrate S2 may refer to a portion in which the top surface of the first substrate S1 and the bottom surface of the second substrate S2 are bonded to each other, and a bonding spreading distance may refer to the diameter of the bonding region or a horizontal width of the bonding region crossing the bonding initiation point.

According to example embodiments, spreading of the bonding region between the first substrate S1 and the second substrate S2 may be spontaneously performed without application of any other external force. For example, the top surface of the first substrate S1 and the bottom surface of the second substrate S2 may each have a surface that is subjected to plasma treatment or wet treatment. An —OH functional group is attached to each of the top surface of the first substrate S1 and the bottom surface of the second substrate S2, and thus, the —OH functional group of the top surface of the first substrate S1 and the —OH functional group of the bottom surface of the second substrate S2 may be spontaneously bonded to each other through hydrogen bonding.

According to embodiments, as the deformable plate 110 is disposed only on the first bonding chuck 10, the first substrate S1 and the second substrate S2 may be bonded to each other as the degree of freedom of any one of the first substrate S1 and the second substrate S2 is eliminated and the other one substrate moves.

Meanwhile, in operation S123, since the second bonding chuck 20 vacuum-adsorbs the outer region of the second substrate S2, the bonding region between the first substrate S1 and the second substrate S2 does not spread to outer regions of the first substrate S1 and the second substrate S2, and may only spread to a point at which the attractive force between surfaces of the first substrate S1 and the second substrate S2 and the elastic restoring force of the second substrate S2 are balanced. The region in which the attractive force and the elastic restoring force are balanced may be defined as the first region D1. In other words, the bonding region between the first substrate S1 and the second substrate S2 while vacuum adsorption is being applied to the first substrate S1 and the second substrate S2 may be understood as the first region D1. As a result, in operation S123, the bonding region between the first substrate S1 and the second substrate S2 may spread to the first region D1, e.g., the bonding region between the first substrate S1 and the second substrate S2 may spread only to the first region D1 among the first and second regions D1 and D2.

Referring to FIGS. 3, 4D, 4E, and 5, in operation S125, when the second bonding chuck 20 releases vacuum adsorption on the outer region of the second substrate S2, the outer region of the second substrate S2 free-falls toward the outer region of the first substrate S1. Thereafter, in operation S127, the outer region of the second substrate S2 and the outer region of the first substrate S1 may be bonded to each other. When the bonding between the outer region of the first substrate S1 and the outer region of the second substrate S2 is completed, a bonded substrate in which an entire bonding surface of the first substrate S1 and an entire bonding surface of the second substrate S2 are bonded to each other. A region where the first substrate S1 and the second substrate S2 are bonded to each other in operation S127 may be defined as a second region D2. In other words, the bonding region between the first substrate S1 and the second substrate S2 after the vacuum adsorption of the second substrate S2 is released may be understood as the second region D2, e.g., the second region D2 may surround an entire perimeter of the first region D1 (FIG. 5)

Referring to FIG. 3, when the bonding between the first substrate S1 and the second substrate S2 is completed, the bonded substrate is unloaded (operation S130). To unload the bonded substrate, the second bonding chuck 20 may be moved in the vertical direction Z away from the first bonding chuck 10, and the first bonding chuck 10 may completely release the vacuum adsorption on the bonded substrate.

FIGS. 6A and 6B are schematic diagrams showing the position of a lower pressing unit of a substrate bonding apparatus according to embodiments.

Referring to FIGS. 6A and 6B, the lower center pressing member 810 may press the center of the bottom surface of the deformable plate 110, and the lower outer pressing members 820 may press the outer portion of the bottom surface of the deformable plate 110. According to embodiments, the plurality of lower outer pressing members 820 may be provided. For example, as illustrated in FIG. 6A, four lower outer pressing members 820 may be provided. In another example, as illustrated in FIG. 6B, eight lower outer pressing members 820 may be provided.

The plurality of lower outer pressing members 820 may be positioned at the same horizontal distance from the lower center pressing member 810. In other words, horizontal distances from the plurality of lower outer pressing members 820 to the lower center pressing member 810 may be substantially the same as one another. The plurality of lower outer pressing members 820 are arranged along an imaginary circle having the lower center pressing member 810 as the center, and the intervals between the lower outer pressing members 820 may be constant. The center angles between adjacent lower outer pressing members 820 of the plurality of lower outer pressing members 820 may be substantially the same. The center angle may be defined between lines interconnecting one lower outer pressing member 820, the lower center pressing member 810, and another lower outer pressing member 820 adjacent to the one lower outer pressing member 820.

Since the second region D2 is a region where bonding of the first substrate S1 and the second substrate S2 is initiated as the outer portion of the top surface of the second substrate S2 is separated from the second base 200, a number of alignment errors could potentially occur in the second region D2. Also, as the second substrate S2 is separated from the second base 200, the deformation of the second substrate S2 may be no longer controlled.

However, the substrate bonding apparatus 1 according to embodiments may reduce alignment errors occurring in the second region D2 by finely adjusting the deformation shape of the deformable plate 110 by using the lower center pressing member 810 and the lower outer pressing members 820 of the lower pressing unit 800. Also, since the lower outer pressing members 820 are located at the same distance from the lower center pressing member 810 in the horizontal direction X or Y and the adjacent lower outer pressing members 820 have the same center angle, the deformable plate 110 may be uniformly deformed. Furthermore, not all of the provided lower outer pressing members 820 may be driven, i.e., only some of the lower outer pressing members 820 may be driven as needed. In other words, the substrate bonding apparatus 1 provided with the plurality of lower outer pressing members 820 may handle different types of substrate bonding, and the number of lower outer pressing members 820 to be driven may be determined as needed.

FIGS. 7A to 7E are schematic diagrams showing a deformable plate of a substrate bonding apparatus according to embodiments.

Referring to FIGS. 2 and 7A to 7E, the thickness of the deformable plate 110 in the vertical direction Z may vary from one region to another. According to example embodiments, the thickness of the deformable plate 110 in the vertical direction Z may vary according to the distance from the center of the deformable plate 110 in the horizontal direction X or Y. In other words, the thickness of the center of the deformable plate 110 in the vertical direction Z and the thickness of the outer portion of the deformable plate 110 in the vertical direction Z may be different from each other.

According to example embodiments, the thickness of the center of the deformable plate 110 in the vertical direction Z may be greater than the thickness of the outer portion of the deformable plate 110 in the vertical direction Z. In other words, the thickness of the deformable plate 110 in the vertical direction Z may decrease in directions from the center of the deformable plate 110 toward the circumference of the deformable plate 110.

According to example embodiments, the top surface of the deformable plate 110 may have a flat shape. For example, as shown in FIGS. 7A to 7E, no steps may be formed on the top surfaces of deformable plates 110-1 to 110-4. The top surface of the first region D1 and the top surface of the second region D2 may be positioned on the same plane on the top surface of the deformable plate 110.

Since the top surface of the deformable plate 110 has a flat shape, the first substrate S1 disposed on the deformable plate 110 may be disposed without a void with the deformable plate 110.

According to example embodiments, the top surface of a deformable plate 110-1 may be flat, and the bottom surface of the deformable plate 110-1 may have a stepped structure, e.g., a stepped profile in a cross-sectional view, in which a step t1 is formed in the vertical direction Z. In other words, the thickness of the bottom surface of the deformable plate 110-1 in the vertical direction Z may discontinuously decrease or increase from the center of the deformable plate 110-1 toward the outer portion of the deformable plate 110-1. Therefore, a surface protruding in the vertical direction Z may be formed on the bottom surface of the deformable plate 110-1. For example, the step t1 may be within the range from about 2 mm to about 4 mm.

According to some embodiments, the surface of the deformable plate 110-1 protruding in the vertical direction Z may be formed at the interface between the first region D1 and the second region D2. According to some embodiments, a surface of a deformable plate 110-2 protruding in the vertical direction Z may be formed to at a point a distance dl apart from the interface toward the second region D2.

According to some embodiments, the stepped structure of a deformable plate 110-3 may have a plurality of steps as shown in FIG. 7C. Therefore, a plurality of surfaces of the deformable plate 110-3 protruding in the vertical direction Z may also be formed on the bottom surface of the deformable plate 110-3.

According to example embodiments, as shown in FIG. 7D, the top surface of a deformable plate 110-4 may have a flat shape and the bottom surface of the deformable plate 110-4 may have a shape inclined from the center of the bottom surface of the deformable plate 110-4 toward the outer portion of the bottom surface of the deformable plate 110-4. In other words, a slope may be formed on the bottom surface of the deformable plate 110-4. The deformable plate 110-4 may have a shape in which the thickness thereof in the vertical direction Z continuously varies from the center of the bottom surface of the deformable plate 110-4 toward the outer portion of the bottom surface of the deformable plate 110-4. According to some embodiments, the deformable plate 110-4 may have a shape in which the thickness thereof in the vertical direction Z continuously decreases from the center of the bottom surface of the deformable plate 110-4 toward the outer portion of the bottom surface of the deformable plate 110-4.

According to embodiments, as shown in FIG. 7E, a deformable plate 110-5 may have a shape in which the top surface of the deformable plate 110-5 is flat and the center portion and the outermost portion of the bottom surface of the deformable plate 110-5 protrude more than the portion of the bottom surface of the deformable plate 110-5 between the center portion and the outermost portion of the bottom surface of the deformable plate 110-5. In other words, the thickness of the outer portion of the deformable plate 110-5 (i.e., the portion of the deformable plate 110-5 between the center portion and the outermost portion of the deformable plate 110-5) in the vertical direction Z may be smaller than the thicknesses of the center portion and the outermost portion of the deformable plate 110-5 in the vertical direction Z. In the same sense, the deformable plate 110-5 may have a shape in which the center portion of the deformable plate 110-5 has a relatively large thickness in the vertical direction Z, the outer portion of the deformable plate 110-5 adjacent to the center portion of the deformable plate 110-5 has a relatively small thickness in the vertical direction Z, and the outermost portion of the deformable plate 110-5 adjacent to the outer portion of the deformable plate 110-5 has a relatively large thickness in the vertical direction Z again. According to some embodiments, thicknesses of the outermost portion and the center portion of the deformable plate 110-5 in the vertical direction Z may be substantially the same.

Since the thickness of the outermost portion of the deformable plate 110-5 in the vertical direction Z is substantially the same as the thickness of the center portion of the deformable plate 110-5 in the vertical direction Z, the outermost portion of the deformable plate 110-5 may be stably adhered to the outer portion of the first base 100 (refer to FIG. 2). In other words, the warpage of the deformable plate 110-5 may be prevented when the outermost portion of the deformable plate 110-5 is adhered onto the first base 100 (refer to FIG. 2).

The deformable plate 110 may be deformed as the lower pressing unit 800 applies pressure to the deformable plate 110 in the vertical direction Z. At this time, a portion of the deformable plate 110 having a relatively small thickness in the vertical direction Z may be deformed more in the vertical direction Z for the same force as compared to a portion of the deformable plate 110 having a relatively large thickness in the vertical direction Z. In other words, when force is applied to the bottom surface of the deformable plate 110, a portion of the deformable plate 110 having a relatively small thickness in the vertical direction Z may have a greater curvature than a portion of the deformable plate 110 having a relatively large thickness in the vertical direction Z. On the contrary, a portion of the deformable plate 110 having a relatively large thickness in the vertical direction Z may be deformed less in the vertical direction Z for the same force as compared to a portion of the deformable plate 110 having a relatively small thickness in the vertical direction Z. In other words, when force is applied to the bottom surface of the deformable plate 110, a portion of the deformable plate 110 having a relatively large thickness in the vertical direction Z may have a smaller curvature than a portion of the deformable plate 110 having a relatively small thickness in the vertical direction Z.

In other words, by forming the deformable plate 110 to have regions with different thicknesses in the vertical direction Z, the shape of the deformable plate 110 that is deformed when the bottom surface of the deformable plate 110 is pressed by the lower pressing unit 800 may be controlled.

According to embodiments, when the thickness of the outer portion of the deformable plate 110 in the vertical direction Z is small, the outer portion is more deformed for the same force applied thereto, and thus the curvature of the outer portion may increase. Therefore, a phenomenon in which only the center of the deformable plate 110 has a large curvature due to concentration of an external force at the center may be prevented.

FIGS. 8A and 8B are schematic diagrams showing shapes of a first base of a substrate bonding apparatus according to embodiments.

Referring to FIG. 8A, a recess R may be formed at the center portion of the top surface of a first base 100-1, e.g., extend to a predetermined depth from the top surface of the first base 100-1. According to embodiments, the recess R may be configured, such that the outer portion of the deformable plate 110 may be attached to the first base 100-1. In other words, the recess R may be configured, such that, when the thickness of the center portion of the deformable plate 110 in the vertical direction Z is relatively large, the center portion of the deformable plate 110 is seated in the recess R and the outer portion of the deformable plate 110 is adhered onto the top surface of the first base 100-1. According to embodiments, the footprint of the recess R may be larger than that of the center portion of the deformable plate 110.

Referring to FIG. 8B, a protrusion P may be formed on the outer portion of the top surface of a first base 100-2. According to example embodiments, the protrusion P may have a ring shape, e.g., a doughnut-like shape, on the X-Y plane (e.g., as viewed in a top view). When the thickness of the outer portion of the deformable plate 110 in the vertical direction Z is smaller than that of the center portion of the deformable plate 110 in the vertical direction Z, the outer portion of the deformable plate 110 may be adhered onto the first base 100-2 through the protrusion P formed on the first base 100-2. The outer portion of the deformable plate 110 needs to be adhered to the outer portion of the first base 100-2, and the outer portion of the deformable plate 110 may be stably adhered onto the first base 100-2 by the protrusion P formed on the first base 100-2.

Embodiments provide a substrate bonding device capable of improving the reliability of a bonding process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate bonding apparatus, comprising:
a first bonding chuck including a first base, a deformable plate on the first base and configured to support a first substrate, and a lower pressurer under the first base and configured to apply pressure to a bottom surface of the deformable plate; and
a second bonding chuck vertically spaced apart from the first bonding chuck, the second bonding chuck including a second base configured to fix a second substrate, and an upper pressurer configured to apply pressure to a top surface of the second substrate,
wherein the deformable plate includes an outer portion surrounding a center portion, a bottom surface of the outer portion of the deformable plate being adhered to the first base, and the center portion being deformable in a vertical direction by the lower pressurer, and
wherein a thickness of the center portion of the deformable plate in the vertical direction and a thickness of the outer portion of the deformable plate in the vertical direction are different from each other.

2. The substrate bonding apparatus as claimed in claim 1, wherein the lower pressurer includes:
a lower center pressing member at a center of the first base and configured to apply pressure to a center portion of the first substrate; and
at least one lower outer pressing member at a periphery of the lower center pressing member and configured to apply pressure to a peripheral portion of the first substrate.

3. The substrate bonding apparatus as claimed in claim 2, wherein:
the at least one lower outer pressing member includes a plurality of lower outer pressing members,
respective horizontal distances from the plurality of lower outer pressing members to the lower center pressing member are substantially the same, and
center angles between adjacent ones of the plurality of lower outer pressing members are substantially the same.

4. The substrate bonding apparatus as claimed in claim 1, wherein the thickness of the outer portion of the deformable plate in the vertical direction is less than the thickness of the center portion of the deformable plate in the vertical direction.

5. The substrate bonding apparatus as claimed in claim 1, wherein a top surface of the deformable plate is flat.

6. The substrate bonding apparatus as claimed in claim 5, wherein the bottom surface of the deformable plate has a stepped structure including a step in the vertical direction.

7. The substrate bonding apparatus as claimed in claim 5, wherein a thickness of the deformable plate in the vertical direction continuously varies in directions from the center portion of the deformable plate toward the outer portion of the deformable plate.

8. The substrate bonding apparatus as claimed in claim 1, wherein the first base includes a recess, the recess extending from a top surface of the first base to a predetermined depth in the vertical direction.

9. The substrate bonding apparatus as claimed in claim 1, wherein the first base includes a protrusion protruding in the vertical direction from a top surface of the first base toward the deformable plate, the protrusion being in an outer portion of the first base and in contact with the deformable plate.

10. The substrate bonding apparatus as claimed in claim 1, wherein a difference between the thickness of the outer portion of the deformable plate in the vertical direction and the thickness of the center portion of the deformable plate in the vertical direction is within a range of about 2 mm to about 4 mm.

11. The substrate bonding apparatus as claimed in claim 1, wherein:
the lower pressurer includes a pressing pin contacting the bottom surface of the deformable plate and an actuator coupled to the pressing pin, and
the thickness of the outer portion of the deformable plate in the vertical direction is less than the thickness of the center portion of the deformable plate in the vertical direction.

12. The substrate bonding apparatus as claimed in claim 1, wherein:
the thickness of the outer portion of the deformable plate in the vertical direction is less than the thickness of the center portion of the deformable plate in the vertical direction,
the lower pressurer includes a plurality of pressing pins and a plurality of actuators respectively coupled to the plurality of pressing pins,
the plurality of pressing pins includes a center pressing pin near the center portion of the deformable plate and outer pressing pins arranged on the outer portion of the deformable plate, and
a protruding length of the center pressing pin from the first base is greater than a protruding length of each of the outer pressing pins from the first base.

13. A substrate bonding apparatus, comprising:
a first bonding chuck including a first base, a deformable plate on the first base and configured to support a first substrate, and a lower pressurer under the first base and configured to apply pressure to a bottom surface of the deformable plate;
a driver coupled to a lower portion of the first bonding chuck and configured to adjust a position of the first bonding chuck;
a second bonding chuck vertically spaced apart from the first bonding chuck, the second bonding chuck including a second base configured to fix an outer portion of a second substrate, and an upper pressurer configured to apply pressure to a top surface of the second substrate; and
an imager above an upper portion of the second bonding chuck, the imager being configured to obtain alignment images of the first substrate and the second substrate,
wherein an outer portion of the bottom surface of the deformable plate is adhered to the first base and is deformable in a vertical direction by the lower pressurer, and
wherein a thickness of a center portion of the deformable plate in the vertical direction and a thickness of an outer portion of the deformable plate in the vertical direction are different from each other.

14. The substrate bonding apparatus as claimed in claim 13, wherein the lower pressurer includes:
a lower center pressing member at a center of the first base and configured to apply pressure to a center portion of the first substrate; and
at least one lower outer pressing member at a periphery of the lower center pressing member and configured to apply pressure to a peripheral portion of the first substrate.

15. The substrate bonding apparatus as claimed in claim 14, wherein the at least one lower outer pressing member includes a plurality of lower outer pressing members, horizontal distances from the plurality of lower outer pressing members to the lower center pressing member being substantially the same, and center angles between adjacent ones of the plurality of lower outer pressing members being substantially the same.

16. The substrate bonding apparatus as claimed in claim 15, wherein:
each of the plurality of lower outer pressing members and the lower center pressing member includes a pressing pin in contact with the bottom surface of the deformable plate and an actuator coupled to the pressing pin, and
a length of the pressing pin of the lower center pressing member is greater than a length of the pressing pin of each of the plurality of lower outer pressing members.

17. The substrate bonding apparatus as claimed in claim 15, wherein the at least one lower outer pressing member includes four to eight lower outer pressing members are provided.

18. A substrate bonding apparatus, comprising:
a first bonding chuck including a first base, a deformable plate on the first base and configured to support a first substrate, and a lower pressurer under the first base and configured to apply pressure to a bottom surface of the deformable plate;
a driver coupled to a lower portion of the first bonding chuck and configured to adjust a position of the first bonding chuck;
a second bonding chuck vertically spaced apart from the first bonding chuck, the second bonding chuck including a second base configured to fix an outer portion of a second substrate, and an upper pressurer configured to apply pressure to a top surface of the second substrate; and
an imager above an upper portion of the second bonding chuck, the imager being configured to obtain alignment images of the first substrate and the second substrate,
wherein:
an outer portion of the bottom surface of the deformable plate is adhered to the first base and is deformable in a vertical direction by the lower pressurer,
a thickness of the deformable plate in the vertical direction at a center portion of the deformable plate is greater than a thickness of the deformable plate in the vertical direction at an outer portion of the deformable plate,
the lower pressurer includes a lower center pressing member at a center of the first base and configured to apply pressure to a center portion of the first substrate, and a plurality of lower outer pressing members at a periphery of the lower center pressing member and configured to apply pressure to a peripheral portion of the first substrate, and
horizontal distances from the plurality of lower outer pressing members to the lower center pressing member are substantially the same, and center angles between adjacent ones of the plurality of lower outer pressing members are substantially the same.

19. The substrate bonding apparatus as claimed in claim 18, wherein a difference between the thickness of the outer portion of the deformable plate in the vertical direction and the thickness of the center portion of the deformable plate in the vertical direction is within a range of about 2 mm to about 4 mm.

20. The substrate bonding apparatus as claimed in claim 18, wherein:
the lower center pressing member includes a center pressing pin and an actuator coupled to the center pressing pin,
the plurality of lower outer pressing members include outer pressing pins and actuators coupled to the outer pressing pins, and
a protruding length of the center pressing pin from the first base is greater than a protruding length of each of the outer pressing pins from the first base.
